(19) United States
(12) Patent Application Publication
(10) Pub. No.: US 2020/0163230 A1
(43) Pub. Date: May 21, 2020

(54) METHOD OF MANUFACTURING ELECTRONIC BOARD, COMPOSITE SHEET, AND ELECTRONIC BOARD

(71) Applicant: LENOVO (SINGAPORE) PTE. LTD., SINGAPORE (SG)

(72) Inventors: Tadashi Kosuga, Yokohama (JP); Tin-Lup Wong, Morrisville, NC (US)

(73) Assignee: LENOVO (SINGAPORE) PTE. LTD., SINGAPORE (SG)

(21) Appl. No.: 16/244,551

(22) Filed: Jan. 10, 2019

Related U.S. Application Data
(60) Provisional application No. 62/768,970, filed on Nov. 18, 2018.

(51) Int. Cl. H05K 3/46; H05K 3/34; H05K 3/30; H05K 1/18

(52) U.S. Cl. CPC H05K 3/4688; H05K 3/3494; H05K 1/181; H05K 3/3426; H05K 3/301

(57) ABSTRACT

A method of manufacturing an electronic board includes preparing a composite sheet having a composite layer that includes a solder part and a resin part, placing the composite layer on a substrate, placing a first electronic component on the composite layer, and heating the solder part up to a temperature at which the solder part of the composite layer is melted within a reflow furnace.

### FIELD OF THE INVENTION

The present invention relates to a method of manufacturing an electronic board, a composite sheet, and the electronic board.

### BACKGROUND OF THE INVENTION

Conventionally, as disclosed in Japanese Unexamined Patent Application Publication No. 2007-59600, a method of mounting electronic components on a substrate by using solder has been performed. Moreover, in order to reinforce solder joints between electronic components and a substrate or a printed circuit board, there has been performed a method of filling up resin materials between the electronic components and the substrate (underfill/encapsulation) or a method of partially applying resin materials to the corners etc. of the electronic components (corner bond/corner fill).

The conventional method has a possibility that the solder joints between the electronic components and the substrate cannot be efficiently and certainly reinforced by using resin materials.

The present invention has been achieved in view of the above problem, and an object of the invention is to provide a method that can efficiently and certainly reinforce a solder joint between an electronic component and a substrate by using a resin material.

### SUMMARY OF THE INVENTION

To solve the problem, a method of manufacturing an electronic board according to the first aspect of the present invention includes: preparing a composite sheet having a composite layer that includes a solder part and a resin part; placing the composite layer on a substrate; placing a first electronic component on the composite layer; and heating the solder part up to a temperature at which the solder part of the composite layer is melted within a reflow furnace.

Moreover, a composite sheet according to the second aspect of the present invention is a composite sheet used for mounting an electronic component on a substrate, the composite sheet including a composite layer that includes a resin part and a solder part.

Moreover, an electronic board according to the third aspect of the present invention includes: a substrate; a first electronic component that is mounted on the substrate with reflow soldering; a second electronic component that is mounted on the substrate with reflow soldering; and underfill that is filled up at least between the first electronic component and the substrate, wherein a melting point T2 of a solder alloy that join the second electronic component and the substrate is higher than a melting point T1 of a solder alloy that join the first electronic component and the substrate.

The above-described aspects of the present invention can efficiently and certainly reinforce a solder joint between an electronic component and a substrate by using a resin material.

### BRIEF DESCRIPTION OF THE DRAWINGS

FIG. 1 is a schematic diagram illustrating an electronic board obtained by a method of manufacturing the electronic board according to a first embodiment;

FIG. 2A is a plan view illustrating a composite sheet according to the first embodiment;

FIG. 2B is a cross-sectional diagram taken along II-II arrows in FIG. 2A;

FIG. 3A is a diagram explaining the method of manufacturing the electronic board according to the first embodiment;

FIG. 3B is a diagram explaining a process following FIG. 3A;

FIG. 3C is a diagram explaining a process following FIG. 3B;

FIG. 3D is a diagram explaining a process following FIG. 3C;

FIG. 4A is a diagram explaining a method of manufacturing an electronic board according to a second embodiment;

FIG. 4B is a diagram explaining a process following FIG. 4A;

FIG. 4C is a diagram explaining a process following FIG. 4B;

FIG. 4D is a diagram explaining a process following FIG. 4C;

FIG. 5A is a plan view illustrating a composite sheet according to a third embodiment;

FIG. 5B is a cross-sectional diagram taken along V-V arrows in FIG. 5A;

FIG. 6A is a cross-sectional diagram illustrating a composite sheet according to a first modified example of the first embodiment;

FIG. 6B is a cross-sectional diagram illustrating a composite sheet according to a second modified example of the first embodiment;

FIG. 6C is a cross-sectional diagram illustrating a composite sheet according to a third modified example of the first embodiment;

FIG. 7A is a diagram explaining a method of manufacturing an electronic board according to a fourth modified example of the first embodiment;

FIG. 7B is a diagram explaining a method of manufacturing an electronic board according to a fifth modified example of the first embodiment; and

FIG. 7C is a diagram explaining a method of manufacturing an electronic board according to a sixth modified example of the first embodiment.

### DETAILED DESCRIPTION OF THE INVENTION

### First Embodiment

Hereinafter, a method of manufacturing an electronic board (mounting board) and a composite sheet used in the manufacturing method according to the first embodiment will be explained with reference to the drawings.

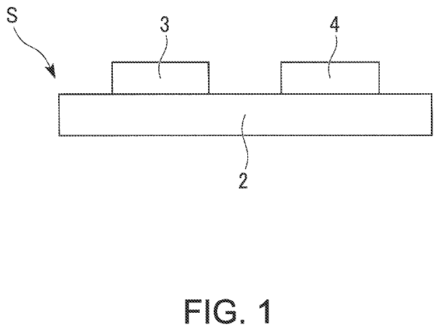

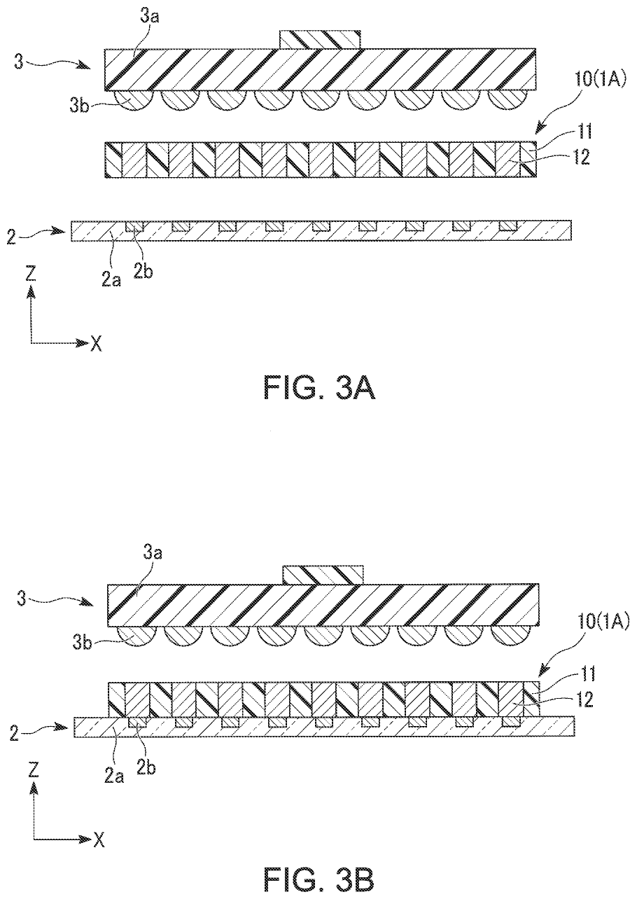

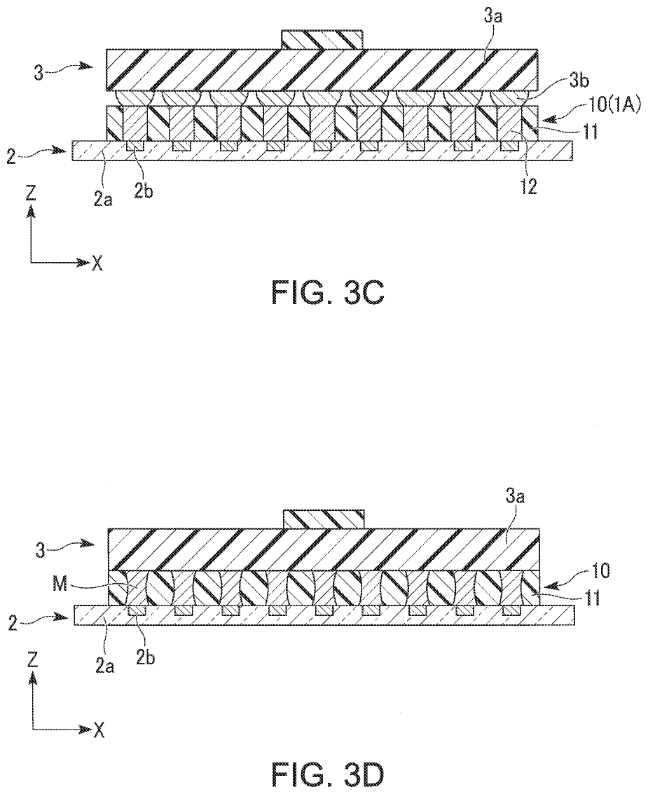

The method of manufacturing the electronic board according to the present embodiment can manufacture an electronic board S as illustrated in FIG. 1, for example. The electronic board S includes a substrate 2 and first and second electronic components 3 and 4 mounted on the substrate 2. The substrate 2 includes a substrate body 2a formed of insulating materials and electrodes 2b formed of electric conductors (see FIG. 3A). The first electronic component 3 and the second electronic component 4 have interfaces electrically connected to the electrodes 2b.

The first electronic component 3 and the second electronic component 4 can employ IC (Integrated Circuit) chip such as LSI (Large Scale Integration) and SSI (Small Scale Integration). Particularly, the first electronic component 3 may employ relatively expensive components such as CPU (Central Processing Unit), GPU (Graphic Processing Unit), memory, and SSD (Solid State Drive), and the second electronic component 4 may employ the other components. The reason will be described later.

The first electronic component 3 and the second electronic component 4 are mounted on the substrate 2 by using reflow soldering. In the present specification, “%” on solder alloy composition is “mass %” unless otherwise specified.

In addition, the electronic board S may not include the second electronic component 4. Alternatively, the electronic board S may include a plurality of the first electronic components 3 or a plurality of the second electronic components 4.

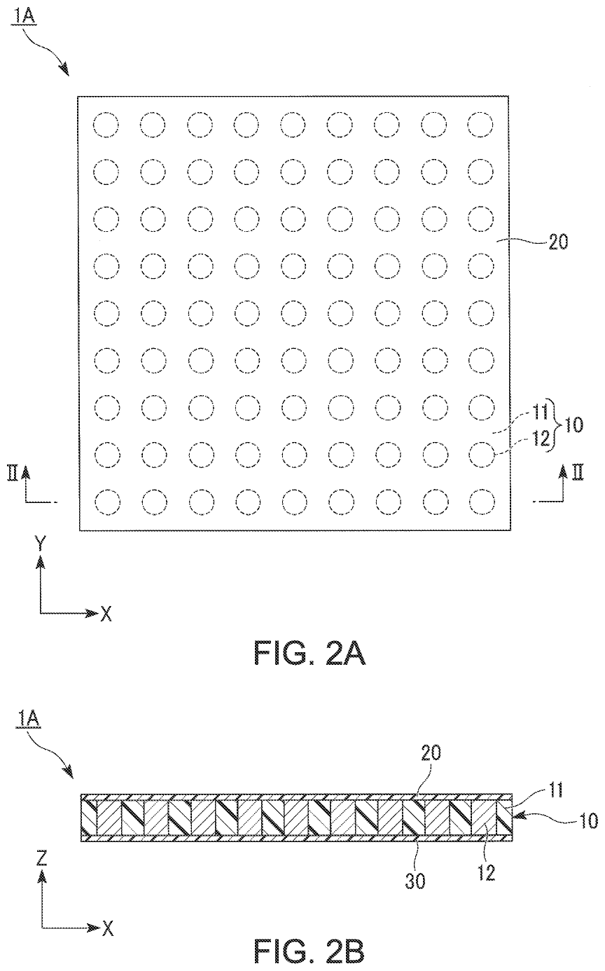

FIGS. 2A and 2B illustrate an example of a composite sheet 1A used in the method of manufacturing the electronic board according to the present embodiment. The composite sheet 1A includes a composite layer 10 that includes a resin part 11 and solder parts 12, a first cover film 20 that covers a top surface of the composite layer 10, and a second cover film 30 that covers a bottom surface of the composite layer 10.

### Definition of Direction

In the present embodiment, the thickness direction of the composite layer 10 indicates a vertical direction Z. One direction perpendicular to the vertical direction Z indicates a horizontal direction X and a direction perpendicular to both directions of the vertical direction Z and the horizontal direction X indicates a front-back direction Y. Along the vertical direction Z, the substrate 2 side and the first-electronic-component 3 side of the composite layer respectively mean the lower and upper sides. Moreover, a planar view means to view a target object from the vertical direction Z.

The resin part 11 is a part that acts as the underfill of the first electronic component 3 in the electronic board S. The resin part 11 can use resin materials (composite resin) including epoxy resin, acrylic resin, silicon resin, etc. In order to improve various resistances such as durability and heat resistance, a filler such as glass may be added to the resin materials of the resin part 11. The resin part 11 may have an adherence property. In this regard, however, the specific material, composition, and property of the resin part 11 are not limited to the above and thus can be appropriately changed.

As illustrated in FIG. 2A, the resin part 11 is formed in a square shape in a planar view. The outer shape of the resin part 11 can be appropriately changed. However, it is preferable that the outer shape has a shape tailored to a main body 3a (see FIG. 3A) of the first electronic component 3. That is to say, if the main body 3a of the first electronic component 3 has a square shape in a planar view, the resin part 11 may have a square shape as illustrated in FIG. 2A. Alternatively, if the main body 3a of the first electronic component 3 has a rectangular shape in a planar view, the resin part 11 may have a rectangular shape.

The composite layer 10 includes the plurality of solder parts 12. The plurality of solder parts 12 are dispersedly arranged with respect to the resin part 11 in an island shape. In the example of FIGS. 2A and 2B, each of the solder parts 12 is formed in a cylindrical shape extending in the vertical direction, and the solder parts are arranged at intervals in the horizontal direction X and the front-back direction Y. In other words, the solder parts 12 are arranged in a grid pattern.

The top surfaces and the bottom surfaces of the solder parts 12 are not covered by the resin part 11. In other words, the solder parts 12 are respectively formed inside a plurality of through-holes provided in the resin part 11 and are exposed on the top surface and the bottom surface of the composite layer 10.

The arrangement of the solder parts 12 can be appropriately changed, but it is preferable that the solder parts are arranged in accordance with the positions of interfaces 3b of the first electronic component 3. For example, FIG. 3A illustrates the case where the first electronic component 3 is BGA (Ball Grid Array) and hemispherical solder balls (bumps) as the interfaces 3b are arranged on the bottom surface of the main body 3a side by side in a grid pattern. The diameter of the solder ball can be appropriately changed, but it is preferable that the diameter is around 100 to 1000 μm, for example. When the first electronic component 3 is BGA as illustrated in FIG. 3A, the arrangement of the solder parts 12 as illustrated in FIG. 2A can be employed. In addition, the first electronic component 3 may expose electrode terminals thereof on the bottom surface of the first electronic component 3 without employing the arrangement of solder balls. In that case, the exposed electrode terminals of the first electronic component 3 act as the interfaces 3b, and the electrodes 2b of the substrate 2 and the electrode terminals of the first electronic component 3 are electrically connected to each other only by the solder parts 12 of the composite layer 10.

Although it is not illustrated, the interfaces 3b of the first electronic component 3 may be lead frames (electrodes) that extend from the main body 3a in the horizontal direction X or in the front-back direction Y and then bend downward. In this case, the arrangement of the solder parts 12 in the composite layer 10 may be decided in accordance with the placement positions of the lead frames on the substrate 2. For example, the solder parts 12 may be intermittently arranged along the outer shape of the main body 3a of the first electronic component 3 in a planar view.

The solder parts 12 include solder alloy. The materials of the solder parts 12 can employ, for example, solder paste or cut wire solder. Particularly, when the interfaces 3b of the first electronic component 3 are solder balls, solder alloy, whose melting point is lower than that of the solder balls, is suitable as the materials of the solder parts 12. The solder parts 12 may include a soldering accelerator such as flux.

A resin sheet etc. can be used as the cover films 20 and 30. The specific materials of the cover films 20 and 30 include PET (Polyethylene Terephthalate) and the like.

It is preferable that the melting point (T1 to be described later) of the solder alloy included in the solder parts 12 is a low melting point not more than 150° C. for example. When employing solder alloy (low melting point solder) having a low melting point, a heating temperature in a composite sheet reflow process to be described later can be suppressed to be low and thus an effect caused by a difference of a thermal expansion rate between the substrate 2, the first electronic component 3, and the solder alloy is reduced. Therefore, it is possible to suppress stress concentration on joint parts M during a cooling process after the composite sheet reflow process. Solder alloy having a melting point not more than 150° C. includes Sn—Bi based solder alloy. The specific example of Sn—Bi based solder alloy includes a Sn—Bi solder alloy, a Sn—Bi—Cu solder alloy, a Sn—Bi—Ni solder alloy, a Sn—Bi—Cu—Ni solder alloy, a Sn—Bi—Ag solder alloy, and a Sn—Bi—Sb solder alloy. The solder parts 12 may include one or two or more solder alloys as described above, or may include a solder alloy having another composition.

When adding Cu and Ni to the Sn—Bi solder alloy, it is desirable that it is “Cu: 0.1 to 1.0%” and it is “Ni: 0.01 to 0.1%”. Moreover, in the alloy composition as described above, it is preferable that a Bi-contained amount is 30 to 80%. When the Bi-contained amount is within the above range, a melting point thereof can be made constant at 138° C. for example. By using an alloy having such the Bi-contained amount for the solder parts 12, in the composite sheet reflow process to be described later, the joint parts M (also called solder joints, see FIG. 3D) can be formed while the interfaces 3b press the solder parts 12 by its own weight of the first electronic component 3. Moreover, by further lowering the melting point of the solder alloy of the solder parts 12, it is possible to lower a heating temperature in the composite sheet reflow process to further reduce thermal damage to the first electronic component 3 and the substrate 2. From the viewpoint of sufficiently lowering the melting point of the solder alloy of the solder parts 12, it is desirable that the Bi-contained amount is 35 to 70% and is further desirable that it is 53 to 61%.

In addition, when the interfaces 3b of the first electronic component 3 are solder balls, the materials of the solder balls can employ, for example, a Sn—Cu solder alloy, a Sn—Ag solder alloy, a Sn—Ag—Cu solder alloy, a Sn—Ag—Cu—Ni solder alloy, a Sn—Ag—Cu—Sb solder alloy, a Sn—Ag—Cu—Ni—Sb solder alloy, and the like. It is preferable that these solder alloys show a melting point not to melt during the composite sheet reflow process to be described later, and these solder alloys may be high melting point solder whose melting point is not less than 200° C. for example.

The compositions of the solder alloy of the solder parts 12 and the interfaces 3b as described above are an example, and thus can be appropriately changed. Moreover, the composition (low melting point solder) explained as the solder alloy of the solder parts 12 may be used for the solder alloy of the interfaces 3b. Furthermore, both of the interfaces 3b and the solder parts 12 may be formed with low melting point solder or both may be formed with high melting point solder. In addition, without providing solder on the first electronic component 3, the solder parts 12 may be formed with low melting point solder or with high melting point solder.

Next, there will be explained the method of manufacturing the electronic board using the composite sheet 1A configured as described above. The method of manufacturing the electronic board according to the present embodiment includes a sheet preparing process, a sheet placing process, an electronic component placing process, and the composite sheet reflow process. Hereinafter, each process will be specifically explained.

Sheet Preparing Process

The sheet preparing process is to prepare the composite sheet 1A having the composite layer 10 that includes the solder parts 12 and the resin part 11. The composite sheet 1A may include the cover films 20 and 30 as illustrated in FIG. 2B or may not include these cover films.

When the composite sheet 1A includes the cover films 20 and 30, the present process is to previously remove the cover films 20 and 30 before the sheet placing process and the electronic component placing process and to expose the top surface and the bottom surface of the composite layer 10. Then, as illustrated in FIG. 3A, the substrate 2 and the bottom surface of the composite layer 10 or the first electronic component 3 and the top surface of the composite layer 10 are made face each other in the vertical direction Z.

Sheet Placing Process

The sheet placing process is performed after the sheet preparing process. As illustrated in FIG. 3B, the sheet placing process is to place the composite layer 10 on the substrate 2. At this time, the present process matches the position of the composite layer 10 with the position of the substrate 2 so that the positions of the solder parts 12 match the positions of the electrodes 2b of the substrate 2. The position adjustment may be performed by using image control etc. or by using positioning pins etc. When the resin part 11 has an adherence property, the composite layer 10 and the substrate 2 adhere to each other by making the composite layer 10 have contact with the substrate 2. Therefore, the mismatch of relative positions between the solder parts 12 and the electrodes 2b can be suppressed in the following processes.

In addition, before performing the sheet placing process, solder paste may be secondarily provided on the surfaces of the electrodes 2b of the substrate 2.

Electronic Component Placing Process

The electronic component placing process is performed after the sheet preparing process. The electronic component placing process may be performed after the sheet placing process or may be performed before the sheet placing process. As illustrated in FIG. 3C, the electronic component placing process is to place the first electronic component 3 on the composite layer 10. At this time, the present process matches the position of the first electronic component 3 with the position of the composite layer 10 so that the positions of the interfaces 3b of the first electronic component 3 match the positions of the solder parts 12. The position adjustment may be performed by using image control etc. or may be performed by using positioning pins etc. When the interfaces 3b are solder balls, the solder balls have contact with the top surfaces of the solder parts 12. When the interfaces 3b are lead frames, the lead frames may have contact with the top surfaces of the solder parts 12 or the portions of the lead frames may be inserted into the solder parts 12. When the interfaces 3b are electrode terminals exposed on the bottom surface of the main body 3a of the first electronic component 3, the electrode terminals have contact with the top surfaces of the solder parts 12.

In addition, before performing the electronic component placing process, solder paste may be secondarily provided on the surfaces of the interfaces 3b of the first electronic component 3.

Composite Sheet Reflow Process

The composite sheet reflow process is performed after the sheet placing process and the electronic component placing process. In addition, before performing the composite sheet reflow process, preliminary overheating of, e.g., about 50 to 100° C. may be performed to remove a solvent contained in the solder parts 12. In the composite sheet reflow process, the substrate 2 is put in a reflow furnace to be heated in the state where the composite layer 10 is sandwiched between the first electronic component 3 and the substrate 2. As a result, as illustrated in FIG. 3D, the joint parts M (solder joints) between the interfaces 3b and the solder parts 12 are formed by melting the solder parts 12 of the composite layer 10. In the present specification, the maximum temperature in the composite sheet reflow process is represented with “Tr”. For example, “Tr” is 150 to 180° C. Moreover, the shapes of the interfaces 3b are changed in FIG. 3D, but the shapes of the interfaces 3b may not be changed when the interfaces 3b are lead frames.

In addition, the mounting process of the first electronic component 3 is illustrated in FIGS. 3A to 3D, but it is sufficient that the same sheet placing process and electronic component placing process are also performed on the second electronic component 4 and the composite sheet reflow process is performed on the second electronic component simultaneously with the first electronic component 3.

Moreover, in the composite sheet reflow process, the resin part 11 is also heated and thus has flowability to some extent. For this reason, the shape of the resin part 11 is also changed to surround the joint parts M.

By performing the cooling process after the composite sheet reflow process, the joint parts M and the resin part 11 are cured to stabilize the respective shapes. At this time, because the resin part 11 acts as underfill, the first electronic component 3 and the substrate 2 are adhesively fixed by the resin part 11 to obtain the electronic board S.

As described above, the method of manufacturing the electronic board according to the present embodiment includes: the sheet preparing process of preparing the composite sheet 1A having the composite layer 10 that includes the solder parts 12 and the resin part 11; the sheet placing process of placing the composite layer 10 on the substrate 2; the electronic component placing process of placing the first electronic component 3 on the composite layer 10; and the composite sheet reflow process of heating the solder parts 12 up to a temperature at which the solder parts 12 of the composite layer 10 are melted. Then, the composite sheet reflow process joins the solder parts 12 and the interfaces 3b of the first electronic component 3 to form the joint parts M and bonds the main body 3a of the first electronic component 3 to the substrate 2 by using the resin part 11. Therefore, it is not necessary to form the joint parts M and the underfill in separate processes, and the electronic board S having the raised joint strength between the electronic component 3 and the substrate 2 can be more efficiently manufactured.

Moreover, if the present embodiment is employed, the joint parts M can be covered without a gap and thus the joint parts M can be surely reinforced by optimizing the thickness of the composite layer 10 and the amount of solder of the solder parts 12 in the composite sheet 1A.

Moreover, the composite sheet 1A according to the present embodiment includes the composite layer 10 that includes the resin part 11 and the solder parts 12. The method of manufacturing the electronic board as described above can be executed by using the composite sheet 1A.

Furthermore, the composite sheet 1A may include the first cover film 20 that covers the top surface of the composite layer 10 and the second cover film 30 that covers the bottom surface of the composite layer 10. By this configuration, even if the resin part 11 has an adherence property, the composite sheet 1A can be easily distributed and stored. Alternatively, even if a volatile substance (flux, etc.) is contained in the solder parts 12, the volatilization of the volatile substance can be suppressed when distributing and storing the composite sheet 1A. In this viewpoint, it is preferable that the cover films 20 and 30 are formed of materials having low breathability.

### Second Embodiment

Next, the second embodiment according to the present invention will be explained, but the basic configuration of the second embodiment is similar to that of the second the first embodiment. For this reason, the same components have the same reference numbers and their explanations are omitted, and an explanation is provided about only different points.

The present embodiment is different from the first embodiment in terms of including a preliminary mounting process to be explained later before the sheet placing process and the electronic component placing process.

Preliminary Mounting Process

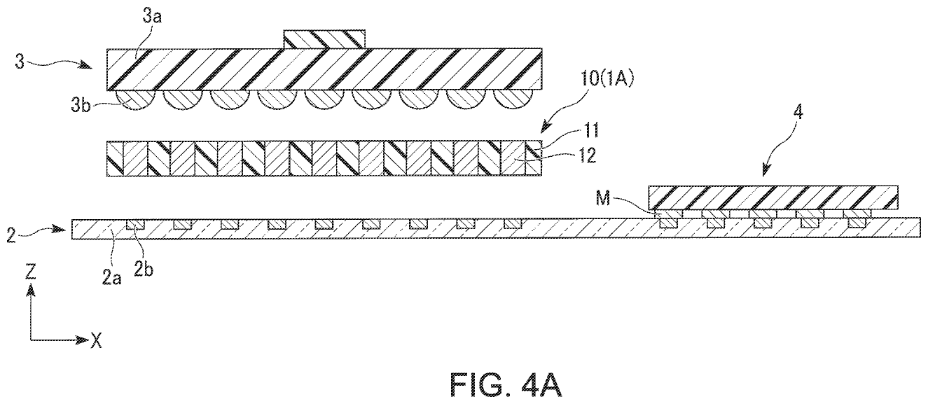

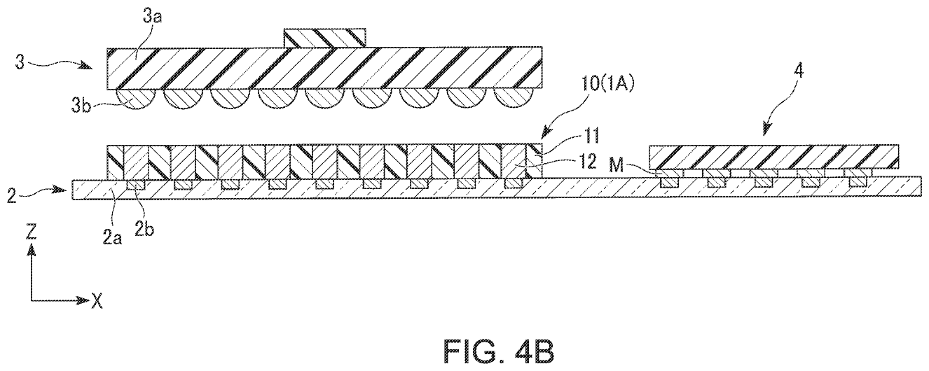

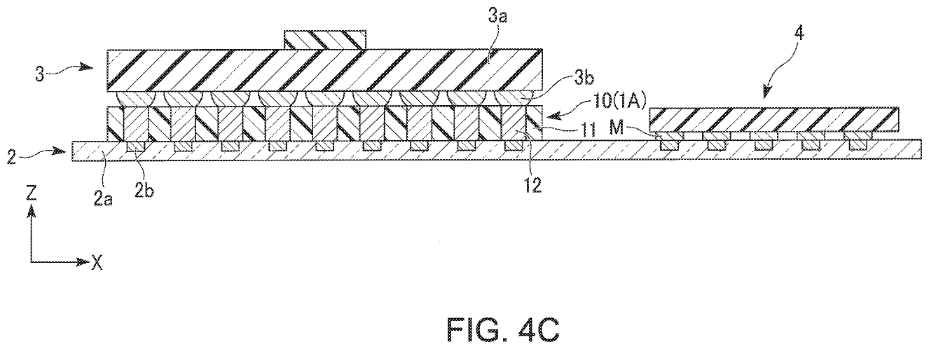

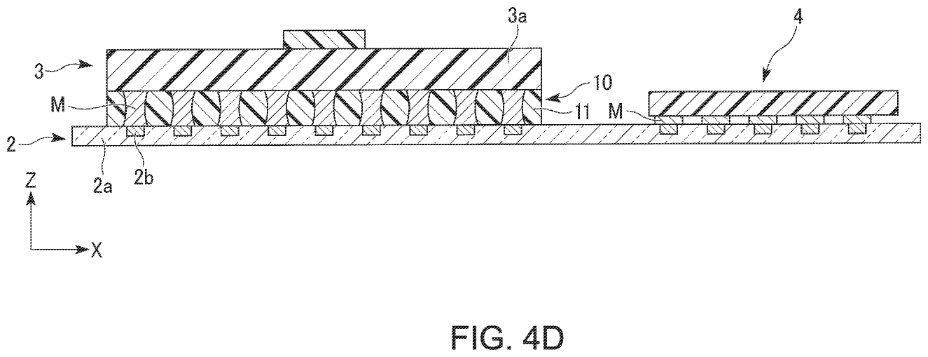

The preliminary mounting process is to previously mount the second electronic component 4 on the substrate 2 before the sheet placing process and the electronic component placing process. For this reason, as illustrated in FIG. 4A, the second electronic component 4 is already mounted on the substrate 2 before mounting the first electronic component 3. The second electronic component 4 is electrically connected to the electrodes 2b of the substrate 2 by joint parts M (solder joints). In the preliminary mounting process, it is preferable that the second electronic component 4 is mounted on the substrate 2 with reflow soldering. Moreover, a method of mounting the second electronic component 4 on the substrate 2 with reflow soldering may use the method described in the above first embodiment or may use the existing method of applying and reflowing solder paste onto the electrodes 2b of the substrate 2.

In the present embodiment, as illustrated in FIGS. 4A to 4D, the processes for mounting the first electronic component 3 are performed in the state where the second electronic component 4 is previously mounted on the substrate 2.

The sheet preparing process, the sheet placing process, the electronic component placing process, and the composite sheet reflow process for mounting the first electronic component 3 are the same as those of the first embodiment.

The present embodiment is preferable when the first electronic component 3 is relatively expensive or is comparatively difficult to be obtained and the second electronic component 4 is relatively inexpensive or is comparatively easy to be obtained, for example. The reason is that relatively-inexpensive or comparatively-easily-obtainable the second electronic component 4 is previously mounted on the substrate 2 and then the first electronic component 3 can be mounted in accordance with the demand of the electronic board S. Moreover, the present embodiment is also preferable when it is unnecessary to provide underfill between the second electronic component 4 and the substrate 2 and/or when the reliability of this underfill may be lower than the reliability of the underfill between the first electronic component 3 and the substrate 2.

In the present embodiment, assuming that the melting point of solder alloy of the solder parts 12 in the composite layer 10 is “T1” and the melting point of solder alloy used for the reflow soldering of the second electronic component 4 is “T2”, it is preferable that “T2” is higher than “T1” (T2>T1). For example, when the low melting point solder alloy whose “T1” as explained in the first embodiment is not more than 150° C. is used for the solder parts 12 of the composite sheet 1A, it is preferable that “T2” is around 180° C. By selecting a solder alloy whose melting point is higher than “T1” as a solder alloy used for the reflow soldering of the second electronic component 4, the joint parts M (solder joints) of the second electronic component 4 can be prevented from being re-melted in the composite sheet reflow process.

Furthermore, in that case, it is desirable that the maximum temperature Tr in the composite sheet reflow process satisfies the relationship of “T1<Tr<T2” and is a temperature at which the joint parts M of the second electronic component 4 are not melted during the composite sheet reflow process. If “Tr” is within this temperature region, it can be suppressed that the solder joint of the second electronic component 4 becomes unstable during the composite sheet reflow process.

In addition, when the maximum temperature in the reflow process included in the preliminary mounting process is represented by “Tp”, the maximum temperature Tp in the reflow process included in the preliminary mounting process is not less than “T2” and, for example, “Tp” is not less than 190° C. In summary, it is preferable that it is “T1<Tr<T2<Tp”.

As described above, the method of manufacturing the electronic board according to the present embodiment includes previously mounting the second electronic component 4 on the substrate 2 by reflow soldering, and the melting point T2 of solder alloy that joins the second electronic component 4 and the substrate 2 is higher than the melting point T1 of solder alloy of the solder parts 12 in the composite sheet 1A. By this configuration, as described above, even if the first electronic component 3 and the second electronic component 4 are mounted on the substrate in separate processes, it is possible to secure the reliability of the electronic board S.

Moreover, according to the present embodiment, there is obtained the electronic board S that includes: the substrate 2; the first electronic component 3 mounted on the substrate 2 with reflow soldering; the second electronic component 4 mounted on the substrate 2 with reflow soldering; and the underfill filled up at least between the first electronic component 3 and the substrate 2. Moreover, there is obtained the electronic board S in which it is suppressed that the joint parts M (solder joints) of the second electronic component 4 are re-melted in the composite sheet reflow process as described above because the melting point T2 of solder alloy that joins the second electronic component 4 and the substrate 2 is higher than the melting point T1 of solder alloy that joins the first electronic component 3 and the substrate 2.

### Third Embodiment

Next, the third embodiment according to the present invention will be explained, but the basic configuration of the third embodiment is similar to that of the first embodiment. For this reason, the same components have the same reference numbers and their explanations are omitted, and an explanation is provided about only different points.

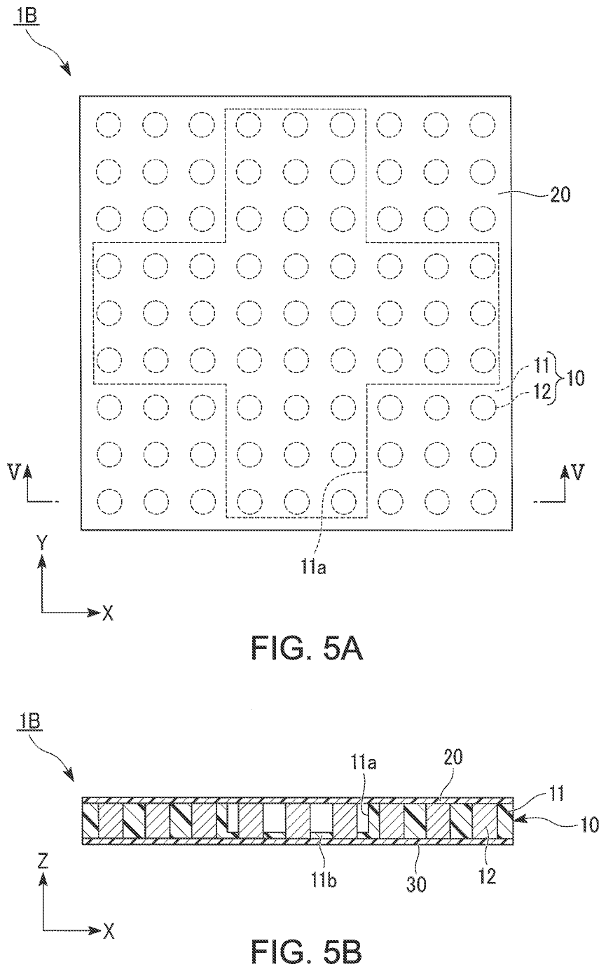

As illustrated in FIGS. 5A and 5B, a composite sheet 1B according to the present embodiment includes a gap 11a and a connection part 11b that are formed in the resin part 11. The gap 11a is a concave portion recessed downward from the top surface of the composite layer 10 and is formed in a cross shape in a planar view. The connection part 11b is provided below the gap 11a. In other words, the connection part lib blocks up the gap 11a from below. The connection part lib maintains the bottom ends of some of the solder parts 12.

The composite sheet 1B according to the present embodiment can be also used similarly to the composite sheet 1A according to the first embodiment. Moreover, when using the composite sheet 1B, selectively providing underfill in the corners of the main body 3a of the electronic component 3 (so-called performing corner bond) can be realized with a simple manufacturing method. Furthermore, when the first electronic component 3 is BGA, the interfaces 3b in the central portion of the first electronic component 3 can be also connected to the electrodes 2b of the substrate 2 while performing corner bond.

The first to third embodiments are common in that the resin part 11 has a shape configured to cover at least the positions on the substrate 2 corresponding to the four corners of the first electronic component 3 in a planar view.

In this regard, however, the third embodiment is different from the first and second embodiments in that the resin part 11 provides the gap 11a in a portion other than the positions on the substrate 2 corresponding to the four corners of the first electronic component 3 in a planar view.

In FIG. 5A, substantially square-shaped areas (portions excluding the gap 11a) constituted by the resin part 11 and the solder parts 12 are provided in the four corners of the composite layer 10. However, the shape of the areas provided in the four corners can be appropriately changed. For example, the shape may be a triangle shape etc. In this case, the gap 11a may not be a cross shape in a planar view.

In addition, the technical scope of the present invention is not limited to the embodiments and various modifications may be made without departing from the spirit or scope of the general inventive concept.

For example, the solder parts 12 are cylindrical in the first to third embodiments, but the shape of the solder parts 12 may be appropriately changed.

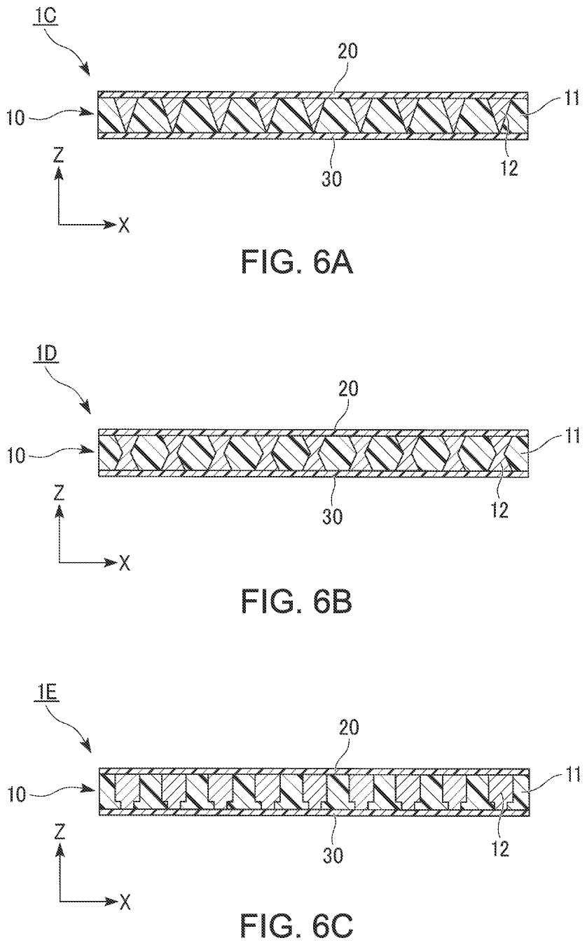

For example, like a composite sheet 1C illustrated in FIG. 6A, the width or the cross-sectional area of each of the solder parts 12 may gradually become smaller toward the downward. Alternatively, the width or the cross-sectional area of each of the solder parts 12 may gradually become smaller toward the upward.

Moreover, for example, like a composite sheet 1D illustrated in FIG. 6B, the width or the cross-sectional area of the upper portion of each of the solder parts 12 may gradually become smaller toward the downward and the width or the cross-sectional area of the lower portion of each of the solder parts 12 may gradually become larger toward the downward.

Moreover, for example, like a composite sheet 1E illustrated in FIG. 6C, the width or the cross-sectional area of the upper portion of each of the solder parts 12 may be larger than the width or the cross-sectional area of the lower portion of each of the solder parts 12. Alternatively, the width or the cross-sectional area of the upper portion of each of the solder parts 12 may be smaller than the width or the cross-sectional area of the lower portion of each of the solder parts 12.

Moreover, the shapes of the plurality of solder parts 12 included in the one composite layer 10 may be formed to be different from each other to be able to take a combination of the shapes illustrated in FIGS. 6A to 6C.

Like these, by changing the width or the cross-sectional area of each of the solder parts 12 along the thickness direction in the cross-sectional view along the thickness direction (the vertical direction Z) of the composite layer 10, it is possible to easily adjust a volume ratio between the solder parts 12 and the resin part 11 in the composite layer 10.

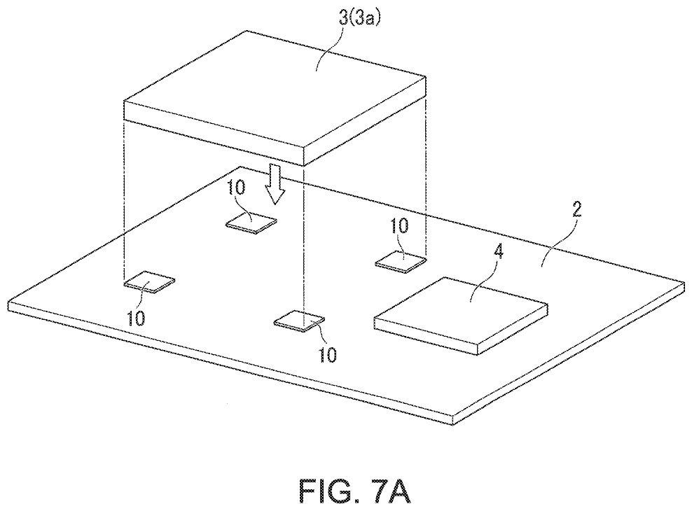

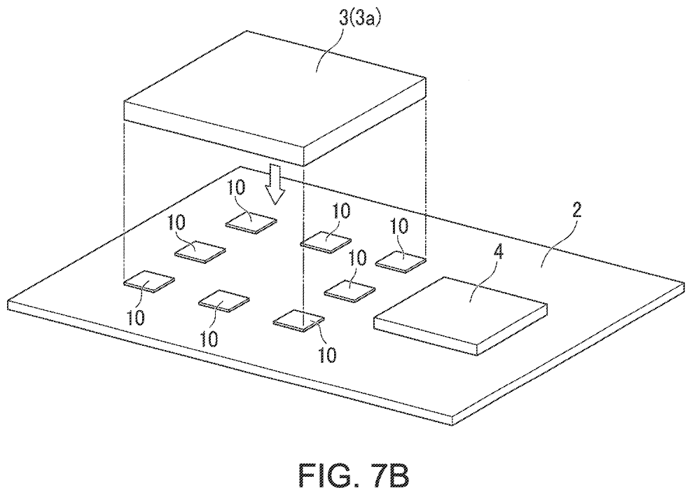

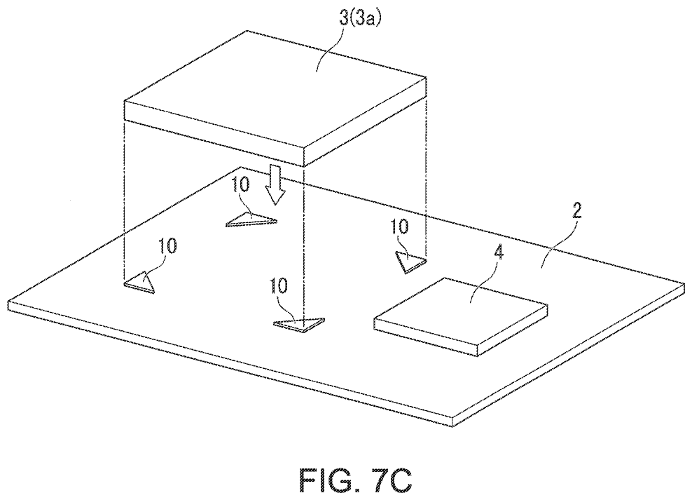

Furthermore, in the third embodiment, corner bond is performed on the first electronic component 3 by forming the gap 11a in the one composite sheet 1B. However, corner bond may be performed by using the four composite sheets 1A whose area is smaller than that of the main body 3a of the first electronic component 3. In this case, the sheet preparing process includes preparing the four composite sheets 1A whose area in a planar view is smaller than that of the main body 3a. As illustrated in FIG. 7A, the sheet placing process includes placing the composite layers 10 of the four composite sheets 1A at the respective positions on the substrate 2 corresponding to the four corners of the main body 3a. Then, the electronic component placing process includes placing the four corners of the first electronic component 3 on the respective composite layers 10.

In addition, as illustrated in FIG. 7B, the composite layer 10 may be placed at the position corresponding to the vicinity of the center of each of four sides in addition to the corners of the first electronic component 3. In this case, the filling places of the resin part 11 using the composite sheets 1A are eight places.

In FIG. 7B, the composite layers 10 are arranged at the positions corresponding to the central portions of all sides of the first electronic component 3, but the composite layers 10 may be arranged at only the positions corresponding to the central portions of some of the four sides. Moreover, a plurality of the composite layers 10 may be arranged side by side at the positions corresponding to one side of the first electronic component 3. That is to say, the number of the composite layers 10 is not limited to four (FIG. 7A) or eight (FIG. 7B), and may be five to seven or nine or more.

That is to say, the present embodiment may include preparing the composite sheets 1A to have at least the four independent composite layers 10 and placing the composite layers 10 at the respective positions on the substrate 2 corresponding to the four corners of the first electronic component 3. Even with this method, corner bond can be performed on the first electronic component 3. In addition, in FIGS. 7A and 7B, the electronic component placing process is performed after the sheet placing process, but this order may be reversed. That is to say, after providing the plurality of composite layers 10 on the bottom surface of the first electronic component 3, the first electronic component 3 may be placed on the substrate 2.

Moreover, the shape of the composite layers 10 may be appropriately changed. For example, as illustrated in FIG. 7C, the composite layers 10 having a triangle shape may be arranged at the positions corresponding to the four corners of the first electronic component 3. Furthermore, the composite layers 10 may have a quadrangle or a shape other than a triangle.

In addition, without departing from the spirit or scope of the general inventive concept, the components in the above-described embodiments can be appropriately replaced by well-known components and the above-described embodiments and modified examples may be appropriately combined.

1. A method of manufacturing an electronic board, the method comprising:
preparing a composite sheet having a composite layer that includes a resin part in a sheet shape having through-holes and solder parts inside the though-holes, wherein the solder parts are arranged in accordance with positions of interfaces of a first electronic component;
placing the composite layer as a monolithic sheet on a substrate;
placing the first electronic component on the composite layer; and
heating the solder part to a temperature at which the solder part of the composite layer is melted within a reflow furnace.

2. The method of manufacturing the electronic board according to claim 1, wherein: a second electronic component is mounted on the substrate, before the first electronic component is placed, by reflow soldering, and a melting point T2 of a solder alloy that joins the second electronic component and the substrate is higher than a melting point T1 of a solder alloy of the solder part.

3. The method of manufacturing the electronic board according to claim 2, wherein a maximum temperature Tr, at which the solder part of the composite layer is melted, is higher than T1 and is lower than T2.

4. The method of manufacturing the electronic board according to claim 1, wherein the resin part has a shape configured to cover positions on the substrate corresponding to at least four corners of the first electronic component in a planar view.

5. The method of manufacturing the electronic board according to claim 4, wherein the resin part has a gap in a portion other than the positions on the substrate corresponding to the four corners in a planar view.

6. A method of manufacturing the electronic board, the method comprising:
preparing a composite sheet having a composite layer that includes a solder part and a resin part;
placing the composite layer on a substrate;
placing a first electronic component on the composite layer; and
heating the solder part to a temperature at which the solder part of the composite layer is melted within a reflow furnace, wherein:
the resin part has a shape configured to cover positions on the substrate corresponding to at least four corners of the first electronic component in a planar view,
the composite sheet has at least four independent composite layers, and
the placing includes placing the composite layers at the positions on the substrate corresponding to the four corners of the first electronic component.

7. A composite sheet used for mounting an electronic component on a substrate, the composite sheet, comprising: a composite layer that includes a resin part and a solder part.

8. The composite sheet according to claim 7, further comprising: a first cover film that covers a top surface of the composite layer; and a second cover film that covers a bottom surface of the composite layer.

9. The composite sheet according to claim 8, wherein a width of the solder part is changed along a thickness direction of the composite layer in a cross-sectional view along the thickness direction.

10. The composite sheet according to claim 9, wherein the solder part is exposed on the top surface and the bottom surface of the composite layer.

11. An electronic board, comprising: a substrate; a first electronic component mounted on the substrate with reflow soldering; a second electronic component mounted on the substrate with reflow soldering; and underfill that is at least between the first electronic component and the substrate, wherein: a melting point T2 of a solder alloy that joins the second electronic component and the substrate is higher than a melting point T1 of a solder alloy that joins the first electronic component and the substrate

12. The method of manufacturing the electronic board according to claim 1, wherein:
the composite sheet includes a cover film that covers at least one of a top surface and a bottom surface of the composite layer, and
before the composite layer placing process and the first electronic component placing process, the cover film is removed, and the top surface and the bottom surface of the composite layer are exposed.
